(19) United States
(12) Patent Application Publication
(10) Pub. No.: US 2004/0098651 A1
(43) Pub. Date: May 20, 2004

(54) System and method for generating self-checking data having information content in an error detection field

(76) Inventor: Colm Marin Rice, Dublin (IE)

Correspondence Address: Brian L. Michaelis, Esq., Brown Rudnick Berlack Israels, LLP, One Financial Center, Boston, MA, 02111, US

(21) Appl. No.: 10/298,628

(22) Filed: Nov. 18, 2002

(51) Int. Cl. H03M 13/00

(52) U.S. Cl. 714/752

(57) ABSTRACT

An error correction method which includes information-containing data in error correction fields thereby conserving memory space. Calculation of the error correction field can be performed using a formula that includes identifying data such as a company identification number. Memory space that would otherwise be used to provide space for a company identifier number in the source field, for example, can be saved by encoding the company identifier number into the error correction digits. The encoding step can be performed as part of the error correction formula processing so that additional encoding steps are not required

### FIELD OF THE INVENTION

The present invention relates to the field of error checking data and more particularly to computing a self checking data field that includes information content.

### BACKGROUND OF THE INVENTION

Error detection and correction technology is commonly applied in computer memory arrays to economically reduce the probability of undetected errors. Error detection codes are able to determine if a message has been corrupted and is not valid but cannot provide details about the nature of the error. Contrarily, error correction codes are known that both detect and correct certain types of errors in a message.

Various methods for calculating an error detection field have been long known in the field of digital computers. A well known example of such calculated error detection field is the parity bit appended to fields of binary information such as data bytes. An exemplary method of implementing a parity bit to check the validity of an associated data field sets the binary value of a parity bit to one if the sum of the bits in the associated data field is even or zero if the sum of the bits in the associate data field is odd or vice versa. During an error checking step, the sum of the data bits is determined and checked against the expected value of the parity bit. An incorrectly set parity bit indicates that data in the data field includes at least one error.

In another illustrative parity bit code, a single bit is appended to a source word to create a code word. The term “source word” is used herein to describe information to be encoded or appended with error detection information. The term “code word” is used herein to refer to information after encoding or after being appended with error correction information. In the present illustrative parity code bit example, the additional bit (the parity bit) is chosen to force the total number of ones in the code word (including the parity bit itself) to be even, using an even parity code or odd using an odd parity code.

Forward error correction (FEC) is a well known error correcting technique wherein a source word is encoded to generate a code word such that an error in the code word can be corrected automatically. Another well known error correcting technique called automatic transmission requests (ARQ) is used in association with data links wherein a receiver requests retransmission of any message it determines to be in error.

The basis of all forms of error detection and correction is redundancy. Error detection and correction using redundancy can be easily understood by considering how a person reading English language text can detect spelling errors. A reader can detect spelling errors because English is a highly redundant language. Although there are 26×26=676 possible combinations of two letters, from AA to ZZ, only about thirty combinations of two letters exist that are valid (i.e. occur in correctly spelled English words). By knowing the valid combinations the reader detects if a pair of letters is not recognized as a valid two letter combination. In the more general case, errors can be detected in a system having a set of valid combinations when an observed combination is not a member of the set of valid combinations.

By adding sufficient redundancy to a code word, construction of a more robust error detecting and correcting code becomes possible. For example, errors in a trivial source word of one bit can be detected and corrected using a code word of three bits. Although there are 2³=8 possible code words, only two valid codes are allowed: 000 and 111. So each valid code is separated by a minimum of three bit changes. A single error which changes only one bit yields a code word that is one unit from the correct value and two units from the other possible values. Thus, if 100, 010, or 001 is received, the correct code word is assumed to be 000 and the corresponding source word 0. Single bit errors are infrequent and, therefore, double bit errors are very rare; so when an invalid code word is received, the closest valid code word can be taken as the corrected data value.

These results can be generalized to any number of bits. Where the number of bits in a source word is m and the number of bits in a code word is n, the redundant bits are given by r=n-m. The total number of possible code words in a binary system is 2ⁿ and the total number of valid code words in a binary system is 2^{m}. Consequently, there are 2ⁿ-2^{m} error states.

Although the use of redundancy is generally efficient in binary systems such as computer memory systems where the improper setting of individual bits is commonly caused by errant voltages in hardware, redundancy is not so useful to detect or correct errors that are caused by manual data entry. For example, it is possible, but impractical to detect and correct manually entered alphanumeric characters by tripling every alphanumeric character entered to a data entry form. This method would detect and correct some errors but miss numerous others because humans are more likely than computers to enter incorrect data redundantly.

Various additional methods are known for creating self checking and self correcting coded data for manual entry or other non binary systems. In at lease one error correction method known in the art, for example, a nine digit decimal (base 10) number is generated as a code word wherein the first eight digits comprise the source word and the final digit is an error checking digit. The value of the error checking digit is calculated by applying a mathematical formula to the individual digits of the source word. An error checking operation can later be performed upon the code word to determine if the mathematical formula as applied to the source word holds true. If an error has occurred and the source word is corrupted then the mathematical formula as applied to the source word will usually not yield the code word with the correct error checking digit. If the formula as applied to the source word does yield the code word with the correct error checking digit then it is at least 90% likely that the source word does not contain an error.

It should be apparent to persons skilled in the art that such methods are not 100% reliable because, for example, a decimal error correction digit could satisfy such an error detection formula by chance ten percent of the time. Additional digits can therefore be dedicated to error correction fields and more complex formulas used to generate the additional error detecting digits and reduce the probability of an undetected error by corresponding orders of magnitude.

In most data processing systems, it is desirable to conserve memory and thereby provide faster processing and larger data storage capacities. Error detection methods such as those described hereinbefore waste memory space on parity bits and error correction digits that could otherwise be used to store information-containing data.

### SUMMARY OF THE INVENTION

The present invention is an error correction method which includes information-containing data in the error correction fields thereby providing multi-use error correction fields.

According to the invention, calculation of the error correction field can be performed using a formula that includes identifying data such as a company identification number. Memory space that would otherwise be used to provide space for a company identifier number in the source field, for example, can be saved by encoding the company identifier number into the error correction digits. The encoding step can be performed as part of the error correction formula processing so that additional encoding steps are not required.

A particular formula for calculating the value of the error correction field can be associated with an entity. The value in the error correction field can thereby perform the dual function of locating data errors and identifying data as being associated with a particular entity. Any numbers of specific formulas can be used to associate data with any number of entities via the value in the error correction field.

Additionally or alternatively, an identifying number associated with an entity can be incorporated into the error correction field. A single formula can thereby be used to combine the entity identifying numbers with the error correction value and store the result in the error correction field. The present invention thereby saves memory space by using the memory space of the error detection/correction fields to store additional data such as an entity identifier.

The present invention provides an error detection methodology that advantageously conserves memory space in data processing applications. The simple methodology is implemented without requiring substantial additional processing. The method according to the invention facilitates early error detection for manual data entry operations.

### BRIEF DESCRIPTION OF THE DRAWINGS

The foregoing and other features and advantages of the present invention will be more fully understood from the following detailed description of the illustrative embodiments, taken in conjunction with the accompanying drawing in which:

FIG. 1 is a flow chart illustrating the steps of an error detection and entity identifying encoding method according to an illustrative embodiment of the present invention;

FIG. 2 is an illustration of a set of exemplary code word formats according to an illustrative embodiment of the present invention

FIG. 3 is a flow chart illustrating the steps of an error checking and entity association method according an illustrative embodiment of the present invention;

FIG. 4 is a flow chart illustrating the steps of an alternative error detection and entity identifying encoding method according to an illustrative embodiment of the present invention; and

FIG. 5 is a flow chart illustrating the steps of an alternative error checking and entity association method according to an illustrative embodiment of the present invention.

### DETAILED DESCRIPTION OF THE DRAWINGS

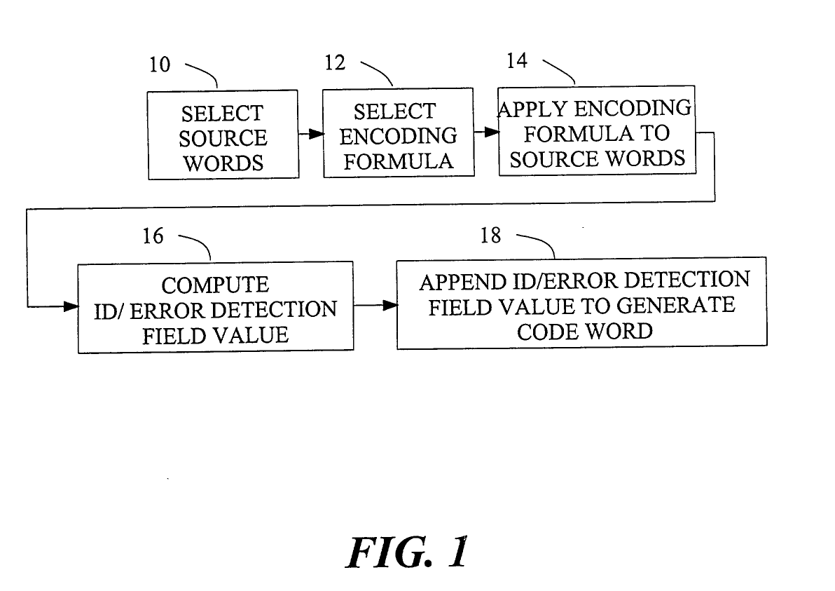

Referring to FIG. 1, an illustrative method of generating code words having entity identifying information encoded therein is described. A select source words step 10 is performed during which any set of identifiers, such as serial numbers, may be selected as a set of source words. Alternatively, a single source word may be selected.

A select encoding formula step 12 is performed wherein a particular formula is selected to apply to the source word or source word set. In an illustrative embodiment of the present invention, the selected encoding formula is associated to a corresponding entity. The term entity is used herein to refer, for example, to a company, division, department, or other unit or segment to which the set of generated code words will be identifiably associated. Different entities, for example, can be associated with different encoding formulas so that the formulas themselves become an entity identifier.

Next, an apply formula step 14 is performed during which the source word or source word set is input or applied to the encoding formula. By applying the encoding formula, an ID/error field value is computed 16. Next, during an append step 18, the computed ID/error detection field value is appended to the source word or set of source words to form a code word or set of code words.

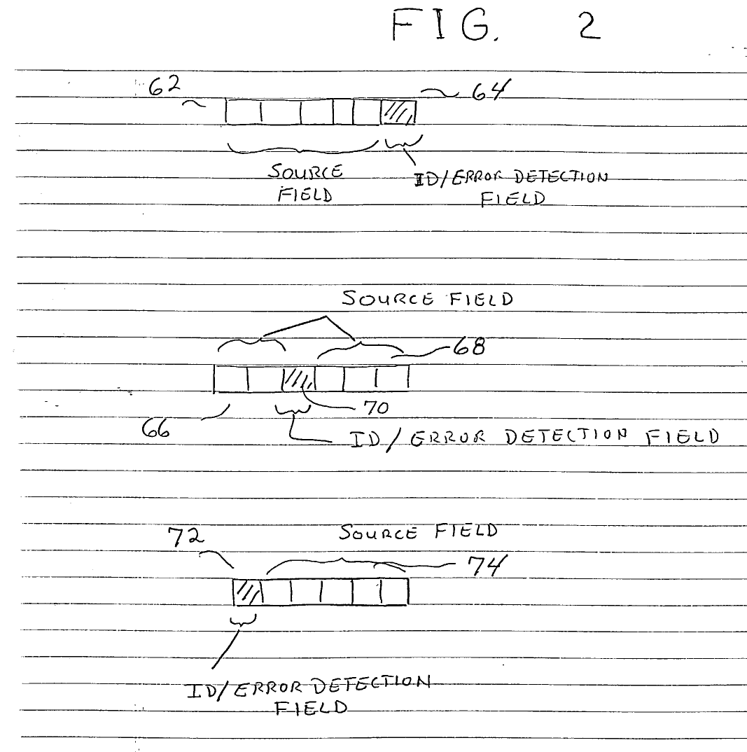

The fields of a code word can be more clearly understood with reference to FIG. 2. Three separate embodiments of a code word are illustrated which are all equally valid embodiments according to the present invention. In the first exemplary code word format, the ID/error detection field 64 is appended to the end of a source word 62. In another exemplary code word format, the ID/error detection fields 70 of a code word can be inserted between source fields 66,68. In a third exemplary code word format, the ID/error detection fields 72 are appended to the beginning or front end of the source fields 74.

Once the set of valid code words have been generated that are identifiably associated with a particular entity, the set can be used for any number of business purposes where later determination of an association with the particular entity may be desired. For example, a set of valid code words can be used as a set of serial numbers, which later can be checked for errors and/or to extract the extra information that is embedded with the error detection field, i.e. the entity identification information.

The code words are thereby associated via the encoding formula to a particular entity. In this way, additional information, i.e. entity identifying information as well as error detection information is embedded in the field that would otherwise only contain error detection information.

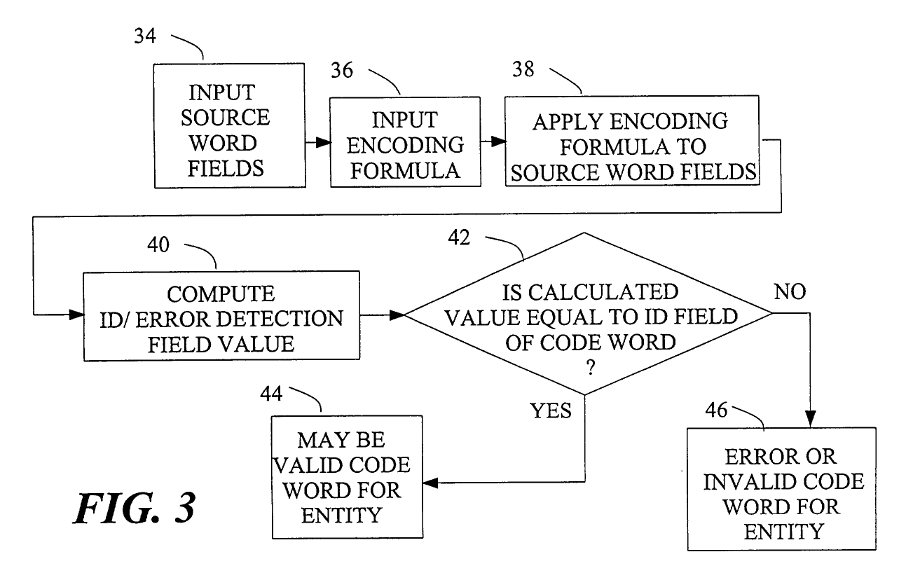

A method of error/identity checking according to an illustrative embodiment of the invention is shown in the flow chart of FIG. 3. An input source word step 34 is performed during which the source word fields are extracted from a code word under test for application to the encoding formula. An input encoding formula step 36 is performed to choose which encoding formula is to be used. In an illustrative embodiment of the invention for example, a code word will be checked against a number of formulas to determine which if any of the formula, associated with a particular entity, generates a valid result. The source word fields are then applied to the selected formula 38 and the ID/error detection field value is computed 40.

The computed ID/error detection field value is then compared 42 to the error detection field of the code word under test. If the calculated error detection field equals the error detection field of the code word under test then the code word under test may be a valid code word 44 of the entity associated with the chosen formula. If the calculated error detection field does not equal the error detection field of the code word under test then the code word under test is not a valid code word 46 for the entity associated with the chosen formula. Where the result is an invalid code word 46, either a data error or an association with a different entity is indicated.

Error detection can be performed using the appropriate formula wherein the validity of data bits is established by the error detection field value matching the calculated error detection field value. If it is desired to associate a code word with an entity, then the various error checking formulas can be applied against the code word to determine which if any of the formulas hold true. If one of the formulas holds true then it is likely that code word is associated with the entity that corresponds to that particular formula. Persons skilled in the art should appreciate that a well constructed formula set can achieve mutually exclusive results in most cases.

An example of the method described above with respect to FIGS. 1 and 3 is provided below:

### EXAMPLE 1

Formula associated with entity A: Add each digit of source word and take the least significant digit of the result as the code field value, use the trailing digit as the code field.

Source word set=1200, 1201, 1202

code word set A=12003, 12014, 12025.

Formula associated with entity B: Add each digit of source word and take the least significant digit of the result as the code field value, use the leading digit as the code field.

Source word set=1200, 1201, 1202

(note: Even though any source word set may be used in practicing the invention, the same source words are used in this example for clarity of the illustration).

code word set B=31200, 41201, 51202.

The results from Example 1 can be used to demonstrate the process of identifying an entity associated with the data according to an illustrative embodiment of the present invention. If it were not known, for example, if data is associated with entity A or B or if the data is valid, the data can be tested according to the invention. Using the data element 41201 from the example, the data element is first tested against formula A by adding the first four digits 4+1+2+0=7 and comparing the last digit of the sum (7) to the error detecting field, the last digit (1) and find that they are not equal. It is thereby determined that the data is not a valid member of set A and therefore either the data is associated with a different entity or there is an error in the data. Here, of course, it would be confirmed by applying the formula associated with entity B that the data element is associated with entity B.

Any code word set can be checked to see if a particular formula or any of the formulas holds true. If none of the formulas hold true there is an error in the code word. A code word that fits the code word set of a particular entity indicates that the code word is likely to be associated with the particular entity.

The method of an illustrative embodiment of the invention allows any number of formulas to be used, wherein the particular formula used can be chosen to accommodate greater error detection accuracy and/or allow greater distinction between different entities, for example by requiring mutually exclusive results. Persons skilled in the art should appreciate that larger error detection fields can be used to increase the reliability of error detection and to allow a larger number of formulas to be used, for example, to distinguish between a larger number of associated entities.

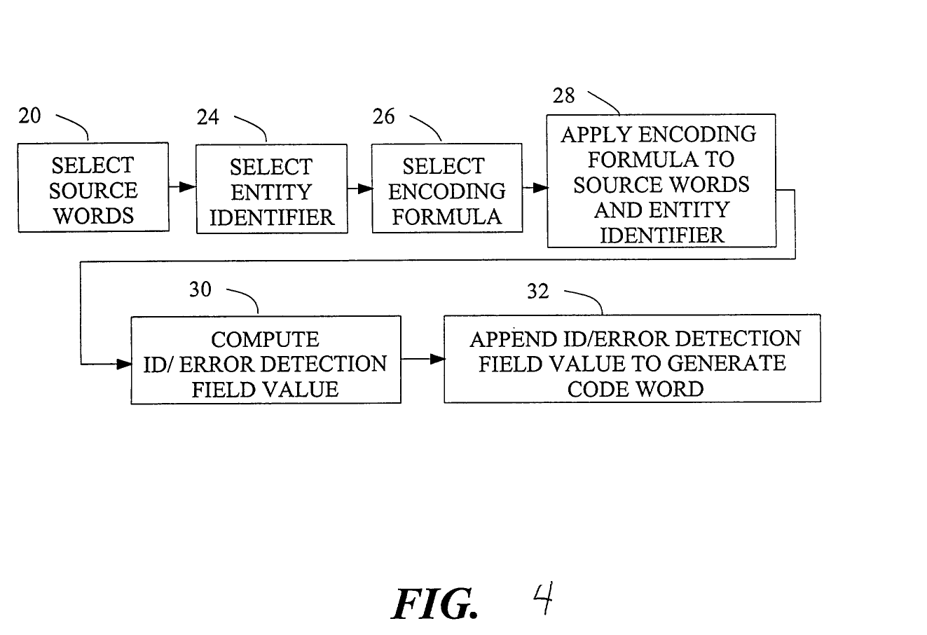

An alternative embodiment of the invention which incorporates further data in the error detection field is described with reference to FIG. 4. A select source words step 20 is performed during which any set of identifiers, such as serial numbers, may be selected as a set of source words. Alternatively, a single source word may be selected. A select entity identifier step 24 is then performed wherein a number is chosen that is uniquely associated with a particular entity.

A select encoding formula step 26 is performed wherein a formula is selected to apply to the source word or source word set and to the unique entity identifier. In an illustrative embodiment of the present invention, the selected encoding formula operates on the selected entity identifier to uniquely associate the resulting code word with a corresponding entity.

Next, an apply formula step 28 is performed during which the source word or source word set and the entity identifier is input or applied to the encoding formula. By applying the encoding formula, an ID/error field value is computed 30. Next, during an append step 32, the computed ID/error detection field value is appended to the source word or set of source words to form a code word or set of code words.

A method of error/identity checking according to the alternative illustrative embodiment of the invention is shown in the flow chart of FIG. 5. An input source word step 48 is performed during which the source word fields are extracted from a code word under test for application to the encoding formula. An input entity identifier step 50 is performed to identify the particular entity the code word under test is to be tested against. An input encoding formula step 52 is performed. The source word fields and the entity identifier are then applied to the encoding formula 54 and the ID/error detection field value is computed 56.

The computed ID/error detection field value is then compared 58 to the error detection field of the code word under test. If the calculated error detection field equals the error detection field of the code word under test then the code word under test may be a valid code word 60 of the entity associated with the chosen formula. If the calculated error detection field does not equal the error detection field of the code word under test then the code word under test is not a valid code word 62 for the entity associated with the chosen formula. Where the result is an invalid code word 62, either a data error or an association with a different entity is indicated.

The method according to the present invention can be performed manually or alternatively on any number of digital computer apparatus. In an illustrative implementation of the present invention, a company can generate all of its invoice numbers or serial numbers using the method of the invention with an embedded invoice set identifier so that the numbers can be confirmed to be valid invoice numbers. In an illustrative embodiment of the invention a set of serial numbers could be generated by using a set of mutually exclusive pseudo-random numbers as source words.

A company can identify data entry errors at an early stage, for example, by incorporating the identification method of the present invention into the data entry system software. Invalid invoice numbers can thereby be rejected at the data entry stage. Further implementations of the invention could be used, for example, to sort invoice numbers for different divisions of a company. Persons skilled in the art should appreciate that various embodiments of the present invention could be used to associate numbers with an entity in a memory-efficient manner.

Although the invention is describe herein in terms of decimal numbers, those skilled in the art should appreciate that the data fields of the invention are not required to be expressed in the base 10 number system. It should be appreciated that the method of the invention is even more effective with number systems having a higher radix such as the hexadecimal number system. Even alpha-numeric systems can be envisioned which encode extra data into an error detection/correction field without departing from the spirit and scope of the present invention.

Although the invention is described herein in terms of entity identifying information being encoded into an error detection/correction field, those skilled in the art should appreciate that information can be other than entity identifying information. For example the information encoded into the error detection/field according to the present invention can be date and time related information or information associated with other properties of the data without departing from the spirit and scope of the present invention.

Although the invention is shown and described with respect to illustrative embodiments thereof, it should be appreciated that the foregoing and various other changes, omissions, and additions in the form and detail thereof could be implemented without departing from the spirit and scope of the underlying invention.

1. A method of incorporating entity identifying information into an error detection field for a source word, comprising the steps of:
associating a particular error detection formula with an entity; and
computing an error detection field value by using said particular error detection formula operating on said source word, whereby said error detection field value includes error detection information and said entity identifying information as a result of computation using said particular error detection formula.

2. The method according to claim 1 further comprising the steps of:
determining whether data is associated with said entity by using said particular error detection formula operating on said source word to generate an error checking value; and
comparing said error checking value with said error detection field value.

3. The method according to claim 1 further comprising the steps of:
associating an additional particular error detection formula with each of at least one additional entities; and
wherein said computing step uses said additional particular error detection formula to associate said data with a particular entity.

4. The method according to claim 3 further comprising the steps of identifying an entity to which data is associated by
using each of said additional particular error detection formula operating on source word fields of said code word to generate a set of error checking values;
applying each member of said set of error checking values to error detection fields of said code word to generate a set of potential entity identifying code words; and
comparing each of said potential entity identifying code words with said code word.

5. A method of incorporating entity identifying information into an error detection field for a source word, comprising the steps of:
associating an entity identifier with an entity;
computing an error detection field value by using an error detection formula operating on said source word and said entity identifier, whereby said error detection field value includes error detection information and entity identifier information.

6. The method according to claim 5 further comprising the steps of:
determining whether data is associated with said entity by using said error detection formula operating on said source word to generate an error checking value; and
comparing said error checking value with said error detection field value.

7. The method according to claim 5 further comprising the steps of:
associating an additional entity identifier with each of at least one additional entity;
wherein said computing step uses said error detection formula to operate on said source word and said additional entity identifier to compute said error detection field value.

8. The method according to claim 7 further comprising the steps of identifying an entity to which data is associated by
using said error detection formula operating on said source word and on each of said entity identifiers to generate a set of error checking values; and
comparing each of said set of error checking values to said error detection field value.

9. A method of incorporating identifying information into an error detection field of a data set comprising the steps of:
selecting a set of source words;
selecting an encoding formula; and
applying said selected encoding formula to each of said set of source words to compute respective ID/error detection field values corresponding to each of said set of source words.
